(19) United States
(12) Patent Application Publication
(10) Pub. No.: US 2026/0036611 A1
(43) Pub. Date: Feb. 5, 2026

(54) RF FRONTEND AND VNA MEASUREMENT SYSTEM

(71) Applicant: Rohde & Schwarz GmbH & Co. KG, Muenchen (DE)

(72) Inventors: AnnaKatharina BURGER, Muenchen (DE); Julian HARMS, Muenchen (DE); Maximilian FRIESINGER, Muenchen (DE); Florian HUBER, Muenchen (DE); Christopher STUMPF, Muenchen (DE)

(21) Appl. No.: 19/223,535

(22) Filed: May 30, 2025

(30) Foreign Application Priority Data
Jul. 30, 2024 (EP) 24 191 691.5

(51) Int. Cl. G01R 27/28

(52) U.S. Cl. CPC G01R 27/28

(57) ABSTRACT

A radio frequency (RF) frontend for a vector network analyzer (VNA) measurement system includes a first frontend portion and a second frontend portion. The first frontend portion includes a first directional unit being configured to couple an RF signal traveling towards at least one port out of at least one measurement path. The first frontend portion further includes a second directional unit being configured to couple an RF signal traveling away from the at least one port out of the at least one measurement path. The second frontend portion includes a frequency combining unit and a switching stage. The frequency combining unit is configured to couple the stimulus RF signal into the at least one measurement path. The frequency combining unit further is configured to couple an RF signal traveling away from the at least one port out of the at least one measurement path.

### CROSS-REFERENCE(S) TO RELATED APPLICATION(S)

This application claims priority from European Patent Application No. 24 191 691.5, filed on Jul. 30, 2024, the entire disclosure of which is disclosed herein in its entirety.

### FIELD OF THE DISCLOSURE

Embodiments of the present disclosure generally relate to a radio frequency, RF, frontend for a vector network analyzer (VNA) measurement system. Embodiments of the present disclosure further relate to a VNA measurement system.

### BACKGROUND

Typically, VNA measurement systems comprise an RF frontend with a measurement signal path via which a measurement signal is received from a device under test, and a reference signal path via which a reference signal is received from a signal source. Usually, these signal paths are optimized for specific types of measurements, such as the measurement of S-parameters of a device under test.

However, if other types of measurements are to be performed by the VNA measurement system, the results may be not optimal, as the existing signal paths are optimized for such specific types of measurements.

Thus, there is a need for an RF frontend and a VNA measurement system that allow for an enhanced number of different measurement types.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a radio frequency (RF) frontend for a vector network analyzer (VNA) measurement system. In an embodiment, the RF frontend comprises at least one port being connectable to a device under test, at least one measurement path that is connected to the at least one port, a first frontend portion, and a second frontend portion.

The first frontend portion comprises a first directional unit being connected to the at least one measurement path and being configured to couple an RF signal traveling towards the at least one port out of the at least one measurement path. The first frontend portion further comprises a second directional unit being connected to the at least one measurement path and being configured to couple an RF signal traveling away from the at least one port out of the at least one measurement path.

The second frontend portion comprises a frequency combining unit and a switching stage. The switching stage comprises an input port, a common port, an output port, a first signal path, and a second signal path. The switching stage has a first switching state, wherein the switching stage is configured to forward a stimulus RF signal received by the input port to the common port via the first signal path in the first switching state. The switching stage has a second switching state, wherein the switching stage is configured to forward an RF signal received by the common port to the output port via the second signal path in the second switching state.

The frequency combining unit is connected to the at least one measurement path. The frequency combining unit comprises a common port that is connected to the common port of the switching stage. The frequency combining unit is configured to couple the stimulus RF signal into the at least one measurement path. The frequency combining unit further is configured to couple an RF signal traveling away from the at least one port out of the at least one measurement path, such that the RF signal is forwarded to the common port of the frequency combining unit.

The second frontend portion comprises a first amplifier that is arranged within the second signal path. The first amplifier is configured to amplify the RF signal received from the measurement path via the frequency combining structure, wherein the second frontend portion is configured to obtain an output signal based on the RF signal received from the measurement path via the frequency combining structure.

The term “the second frontend portion is configured to obtain an output signal based on the RF signal” is understood to denote that the second frontend portion, for example the second signal path, may process the RF signal, thereby obtaining the output signal. For example, the RF signal may be amplified, mixed with an LO signal, and/or converted to another frequency.

The RF frontend according to embodiments of the disclosure comprises the first frontend portion, which is generally configured to process a measurement signal, namely the RF signal coupled out of the measurement path by the second directional unit, and a reference signal, namely the RF signal coupled out of the measurement path by the first directional unit. For example, the first frontend portion may be used for performing S-parameter measurements.

The RF frontend according to embodiments of the disclosure is based on the idea to further add the second frontend portion, which provides two different functionalities associated with the two switching states.

In the first switching state of the switching stage, the second frontend portion forwards the stimulus RF signal to the measurement path, which may then be coupled out by the first directional unit of the first frontend portion. The stimulus RF signal may then be used as reference signal for performing measurements, for example of S-parameters.

In the second switching state of the switching stage, the second frontend portion, for example the frequency combining unit, couples the RF signal traveling away from the at least one port, i.e. the measurement signal, out of the measurement path. The measurement signal may then be processed by the second signal path in an appropriate way, for example by amplifying the measurement signal with the first amplifier.

In an embodiment, the second signal path may be optimized in order to perform a certain type of measurement on the measurement signal. In an embodiment, the second signal path may be a dedicated signal path that is optimized for performing a certain type of measurement, namely a different type of measurement than performed by the first RF frontend portion. For example, the second signal path may be optimized for performing noise figure measurements.

In an embodiment, the first amplifier may be a low-noise amplifier, such that noise figure measurements can be performed on the output signal of the second frontend portion with reduced measurement times being necessary. For example, as the first amplifier adds a particularly small amount of noise to the measurement signal, noise figure measurements can be performed in a particularly precise and time-efficient manner.

In an embodiment, the frequency combining unit may, for example, be established as a diplexer or as a directional coupler, for example as a diplexing forward coupler. However, it is to be understood that the frequency combining unit may be established as any other suitable type of component or circuit being configured to perform the described functionality.

In an embodiment, the first directional unit may, for example, be or comprise a directional coupler. Likewise, the second directional unit may, for example, be or comprise a directional coupler.

In an embodiment, the RF frontend may be a high-frequency frontend being configured to process frequencies above a predefined threshold. For example, the threshold may be 70 GHz. Accordingly, the individual components of the RF frontend, for example of the first frontend portion and of the second frontend portion, may be optimized for performing measurements on RF signals having a frequency above the predefined threshold.

Alternatively, the RF frontend may be a low-frequency frontend being configured to process frequencies below the predefined threshold. Accordingly, the individual components of the RF frontend, for example of the first frontend portion and of the second frontend portion, may be optimized for performing measurements on RF signals having a frequency below the predefined threshold.

According to an aspect of the present disclosure, the input port of the switching stage, for example, is connected or connectable to a signal source that is configured to generate the stimulus RF signal, for example wherein the signal source is comprised in a VNA base system. Thus, the stimulus RF signal generated by the signal source is, in the first switching state of the switching stage, forwarded to the frequency combining unit via the first signal path. The stimulus RF signal is coupled into the measurement path by the frequency combining unit. The stimulus RF signal is then coupled out of the measurement path by the first directional unit of the first frontend portion, and can be used as a reference signal for performing measurements.

In an embodiment, the output port of the switching stage is connected or connectable to a measurement circuit, for example wherein the measurement circuit is comprised in a VNA base system. Accordingly, in the second switching state of the switching stage, the second frontend portion, more precisely the frequency combining unit, couples the RF signal traveling away from the at least one port, i.e. the measurement signal, out of the measurement path. The measurement signal may then be processed by the second signal path in an appropriate way, for example by amplifying the measurement signal with the first amplifier, and the corresponding output signal is forwarded to the measurement circuit for further processing and/or analysis.

As already described above, the second signal path may be optimized for performing a certain type of measurements, such as noise figure measurements. Accordingly, in the second switching state of the switching stage, this certain type of measurements can be performed on the output signal of the switching stage, wherein the output signal corresponds to the measurement signal processed by the second signal path.

In an embodiment, the second frontend portion may comprise a stimulus power amplifier being connected to the input port of the switching stage upstream of the input port. Alternatively or additionally, the second frontend portion may comprise an output amplifier being connected to the output port of the switching stage downstream of the output port.

Accordingly, a power level of the stimulus RF signal, which may be used as reference signal, can be adapted by the stimulus power amplifier. Alternatively or additionally, a power level of the output signal of the switching stage, which may be used as measurement signal for performing the certain type of measurement described above, e.g. a noise figure measurement, can be adapted by the output amplifier.

In an embodiment, the output amplifier may be configured as a low-noise amplifier.

According to another aspect of the present disclosure, the second frontend portion comprises, for example, a mixing unit that is connected to the output port of the switching stage downstream of the output port. For example, the mixing unit may be configured to mix the output signal of the switching stage with a local oscillator signal and to filter the resulting signal appropriately, thereby converting the output signal of the switching stage to an intermediate frequency.

In an embodiment, the mixing unit may be configured for or be optimized for performing the certain type of measurements described above, for example for performing noise figure measurements.

In an embodiment, the mixing unit may be provided downstream of the output amplifier described above.

In an embodiment, the first frontend portion comprises a first pre-amplifier being connected to the first directional unit downstream of the first directional unit, and/or a second pre-amplifier being connected to the second directional unit downstream of the second directional unit. By the first pre-amplifier and the second pre-amplifier, power levels of the reference signal and of the measurement signal can be adapted, respectively.

In an embodiment, the first pre-amplifier may be arranged between the first directional unit and the measurement circuit described above. Likewise, the second pre-amplifier may be arranged between the second directional unit and the measurement circuit described above.

According to another embodiment, the first frontend portion comprises a first mixing unit being connected to the first directional unit downstream of the first directional unit, and/or a second mixing unit being connected to the second directional unit downstream of the second directional unit.

In an embodiment, the first mixing unit may be configured to mix the RF signal coupled out by the first directional unit, i.e. the reference signal, with a local oscillator signal and may filter the resulting signal appropriately, such that the reference signal is converted to an intermediate frequency.

Likewise, the second mixing unit may be configured to mix the RF signal coupled out by the second directional unit, i.e. the measurement signal, with the local oscillator signal and may filter the resulting signal appropriately, such that the measurement signal is converted to an intermediate frequency.

In an embodiment, the first frontend portion and the second frontend portion may be arranged within a common housing. In other words, the common housing may enclose both the first frontend portion and the second frontend portion. However, it is also conceivable that the first frontend portion is arranged in a first housing, while the second frontend portion is arranged in a second housing, wherein the first housing and the second housing are established separately from each other.

Embodiments of the present disclosure further provide a VNA measurement system. In an embodiment, the VNA measurement system comprises an RF frontend according to any one of the embodiments described above. The VNA measurement system further comprises a VNA base system, wherein the VNA base system comprises a measurement circuit and a processing circuit. The processing circuit is configured to control the switching stage to selectively switch between the first switching state and the second switching state.

Regarding the further advantages and properties of the VNA measurement system, reference is made to the explanations given above with respect to the RF frontend, which also hold for the VNA measurement system and vice versa.

In an embodiment, the VNA measurement system may further comprise a signal generator circuit, wherein the signal generator circuit is configured to generate the stimulus RF signal.

In an embodiment, the signal generator circuit may be integrated into the VNA base system. Alternatively, the signal generator circuit may be provided separately from the VNA base system.

According to an aspect of the present disclosure, the VNA base system, for example, is configured to receive a reference signal from the first directional unit. In an embodiment, the VNA base system further is configured to receive a measurement signal from the second directional unit, and wherein the processing circuit is configured to determine at least one measurement parameter based on the reference signal and based on the measurement signal, for example wherein the at least one measurement parameter comprises at least one S-parameter.

However, it is to be understood that any other types of measurements may be performed by the measurement circuit.

In an embodiment, the measurement circuit may comprise at least one analog-to-digital converter (ADC) being configured to digitize the reference signal and/or the measurement signal.

In an embodiment, the measurement circuit may comprise a first ADC being connected to the first directional unit, wherein the first ADC is configured to digitize the reference signal.

In an embodiment, the measurement circuit may further comprise a second ADC being connected to the second directional unit, wherein the second ADC is configured to digitize the measurement signal.

In an embodiment, the VNA base system is configured to receive the output signal of the second frontend portion, wherein the measurement circuit is configured to determine at least one noise parameter based on the output signal. Accordingly, the measurement circuit may determine the at least one noise parameter based on the output signal being processed by the second signal path of the second frontend portion, wherein the second signal path may be optimized for performing the noise parameter measurement.

As already mentioned above, the first amplifier may be a low-noise amplifier, such that the at least one noise parameter can be determined with high precision and with reduced measurement time being necessary.

In an embodiment, the at least one noise parameter may be or comprise a noise figure.

In an embodiment, the measurement circuit may comprise a third ADC being configured to digitize the output signal of the second frontend portion.

In another embodiment, the VNA measurement system comprises at least one further RF frontend, wherein the at least one further RF frontend comprises a measurement path, wherein the measurement path of the RF frontend and the measurement path of the at least one further RF frontend are connected with each other.

Therein, the at least one further RF frontend may be established analogously to the RF frontend described above.

In an embodiment, the measurement path of the at least one further RF frontend may transition seamlessly into the measurement of the RF frontend.

In an embodiment, the measurement path of the at least one further RF frontend and the measurement path of the RF frontend may be established by a single continuous signal line.

In a certain embodiment, the RF frontend may be established as a high-frequency RF frontend, while the at least one further RF frontend may be established as a low-frequency RF frontend. Accordingly, measurement signals having a frequency above the predefined threshold may be processed by the RF frontend, while measurement signals having a frequency below the predefined threshold may be processed by the at least one further RF frontend.

A further aspect of the present disclosure provides, for example, that the at least one further RF frontend comprises a first frontend portion and a second frontend portion. In an embodiment, the VNA measurement system further comprises a measurement switching circuit, wherein the measurement switching circuit is configured to selectively connect the first frontend portion of the RF frontend or the first frontend portion of the at least one further RF frontend to the VNA base system, and/or wherein the measurement switching circuit is configured to selectively connect the second frontend portion of the RF frontend or the second frontend portion of the at least one further RF frontend to the VNA base system. Accordingly, the particular frontend and the particular frontend portion processing the measurement signal and the reference signal can be selected by the measurement switching circuit.

For example, the RF frontend may be selected if a frequency of the reference signal and/or a frequency of the measurement signal is above the predefined threshold, e.g. above 70 GHz. The at least one further RF frontend may be selected if the frequency of the reference signal and/or the frequency of the measurement signal is below the predefined threshold.

In an embodiment, the measurement switching circuit may be controlled by the processing circuit described above, for example automatically based on the frequency of the reference signal and/or based on the frequency of the measurement signal.

In an embodiment, the RF frontend and the at least one further RF frontend may be arranged within a common housing. In other words, the common housing May enclose both the RF frontend and the at least one further RF frontend. Alternatively, the RF frontend and the at least one further RF frontend may be arranged in separate housings.

In an embodiment, the RF frontend and/or the at least one further RF frontend may be provided separately from the VNA base system, i.e. provided in a different housing. Alternatively, the RF frontend and/or the at least one further RF frontend may be integrated into the VNA base system. In other words, the VNA measurement system may comprises a common housing, wherein the common housing encloses the VNA base system as well as the RF frontend and/or the at least one further RF frontend.

In an embodiment, the VNA measurement system comprises a plurality of ports, wherein the VNA measurement system comprises an RF frontend according to any one of the embodiments described above per port. In other words, each port may be connected to a dedicated RF frontend. Thus, optimal processing of multiple measurement signals is ensured, for example of measurement signals having a frequency above the predefined threshold.

Alternatively or additionally, the VNA measurement system may comprise at least one further RF frontend per port. In other words, each port may be connected to at least one dedicated further RF frontend. Thus, optimal processing of multiple measurement signals is ensured, for example of measurement signals having a frequency below the predefined threshold.

In an embodiment, the VNA base system may be connected to each of the frontends and/or to each of the further RF frontends, as described above with respect to the RF frontend and the at least one further RF frontend.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows an example of a VNA measurement system according to an embodiment of the present disclosure;

FIG. 2 shows an example of a processing circuit of the VNA measurement system of FIG. 1 in more detail; and

FIG. 3 schematically shows an example of a VNA measurement system according to another embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

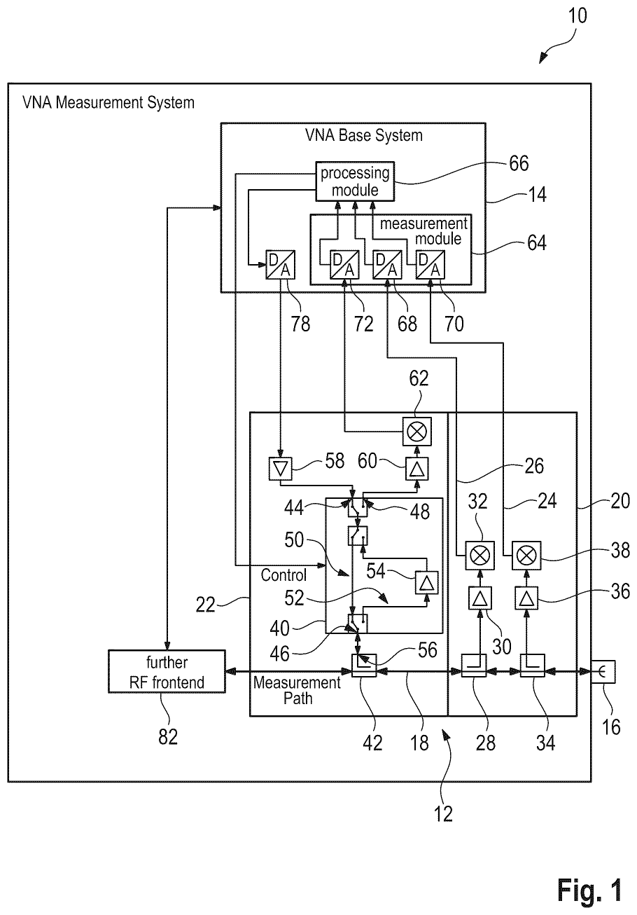

FIG. 1 schematically shows a VNA measurement system 10 comprising an RF frontend 12 and a VNA base system 14. In general, the VNA measurement system 10 is configured to perform measurements on an electronic device under test.

For example, the VNA measurement system 10 may be a vector network analyzer, wherein the RF frontend 12 and the VNA base system 14 may be integrated into the vector network analyzer. Accordingly, the VNA base system 14 and the RF frontend 12 may be arranged within a common housing.

As another example, the VNA base system 14 may be a vector network analyzer, while the RF frontend 12 may be an external frontend for the vector network analyzer. Accordingly, the RF frontend 12 and the VNA base system 14 may be provided in separate housings.

In an embodiment, the VNA measurement system 10 comprises at least one port 16 that is connectable to the device under test. In an embodiment, the RF frontend 12 may comprise the at least one port 16. However, it is to be understood that the VNA measurement system 10 may comprise a plurality of ports. In this case, the VNA measurement system 10 may comprise a plurality of RF frontends, wherein a dedicated RF frontend may be associated with each of the plurality of ports.

Without restriction of generality, the exemplary case of a single port 16 and a single RF frontend 12 is described hereinafter.

The RF frontend 12 comprises a measurement path 18 that is connected to the port 16. In the embodiment of FIG. 1, the RF frontend 12 comprises a first frontend portion 20 and a second frontend portion 22, wherein the measurement path 18 extends through both the first frontend portion 20 and the second frontend portion 22.

In an embodiment, the first frontend portion 20 comprises a measurement signal path 24 and a reference signal path 26. The reference signal path 26 is connected to the measurement path 18 by a first directional unit 28. The first directional unit 28 is configured to couple an RF signal traveling in the measurement path 18 towards the port 16 into the reference signal path 26. The RF signal coupled into the reference signal path 26 is a reference signal.

Further, the first directional unit 28 is configured to forward the RF signal traveling in the measurement path 18 towards the port 16 to the port 16. The RF signal forwarded to the port 16 may be applied to the device under test via the port. For example, the first directional unit 28 may be established as a directional coupler.

In an embodiment, the reference signal path 26 further comprises a first pre-amplifier 30 that is connected to the first directional unit 28 downstream of the first directional unit 28. The first pre-amplifier is configured to amplify the reference signal described above.

In an embodiment, the reference signal path 26 further comprises a first mixing unit 32 that is provided downstream of the first pre-amplifier 30. The first mixing unit 32 may be configured to mix the reference signal with a local oscillator signal and to filter the resulting signal in order to select a desired intermediate frequency.

In the embodiment of FIG. 1, the measurement signal path 24 is connected to the measurement path 18 by a second directional unit 34. The second directional unit 34 is configured to couple an RF signal traveling in the measurement path 18 away from the port 16 into the measurement signal path 24. The RF signal coupled into the measurement signal path 24 is a measurement signal that may be received from the device under test via the port 16.

In an embodiment, the second directional unit 34 is configured to forward the RF signal traveling in the measurement path 18 away from the port 16 to the second frontend portion 22. For example, the second directional unit 34 may be established as a directional coupler.

In an embodiment, the measurement signal path 24 further comprises a second pre-amplifier 36 that is connected to the second directional unit 34 downstream of the second directional unit 34. The second pre-amplifier 36 is configured to amplify the measurement signal.

In an embodiment, the measurement signal path 24 further comprises a second mixing unit 38 that is provided downstream of the second pre-amplifier 36. The second mixing unit 38 may be configured to mix the reference signal with a local oscillator signal and to filter the resulting signal in order to select a desired intermediate frequency.

In an embodiment, the second frontend portion 22 comprises a switching stage 40 as well as a frequency combining unit 42 that connects the switching stage 40 to the measurement path 18. Therein, the switching stage 40 comprises an input port 44, a common port 46, and an output port 48.

The switching stage 40 also comprises a first signal path 50 that extends between the input port 44 and the common port 46. The switching stage 40 further comprises a second signal path 52 that extends between the common port 46 and the output port 48.

In an embodiment, the second signal path 52 comprises a first amplifier 54. For example, the first amplifier 54 may be a low-noise amplifier.

In an embodiment, the switching stage 40 has a first switching state, wherein the switching stage 40 is configured to forward a stimulus RF signal received by the input port 44 to the common port 46 via the first signal path 50 in the first switching state.

The switching stage 40 also has a second switching state, wherein the switching stage 40 is configured to forward an RF signal received by the common port 46 to the output port 48 via the second signal path 52 in the second switching state.

In an embodiment, the frequency combining unit 42 comprises a common port 56 that is connected to the common port 46 of the switching stage 40. In general, the frequency combining unit 42 is configured to couple an RF signal received from the switching stage 40 into the measurement path 18.

Further, the frequency combining unit 42 is configured to couple out an RF signal traveling in the measurement path 18 away from the port 16, such that the RF signal, namely the measurement signal received from the device under test via the port 16, is forwarded to the switching stage 40. For example, the frequency combining unit 42 may be a diplexer or a directional coupler, for example a diplexing forward coupler.

In an embodiment, the second frontend portion 22 may further comprise a stimulus power amplifier 58 that is connected to the input port 44 of the switching stage 40 upstream of the input port 44. The second frontend portion 22 may further comprise an output amplifier 60 that is connected to the output port 48 of the switching stage 40 downstream of the output port 48. Downstream of the output amplifier 60, a mixing unit 62 may be provided.

In an embodiment, the VNA base system 14 comprises a measurement circuit 64 and a processing circuit 66. The measurement circuit 64 is connected to the measurement signal path 24, the reference signal path 26, as well as the second signal path 52, or more precisely to the output port 48 of the switching stage 40.

In an embodiment, the measurement circuit 64 comprises a first ADC 68 that is connected to the reference signal path 26 and that is configured to digitize the reference signal. The measurement circuit 64 also comprises a second ADC 70 that is connected to the measurement signal path 24 and that is configured to digitize the measurement signal. In an embodiment, the measurement circuit 64 may comprise a third ADC 72 that is connected to the output port 48 of the switching stage 40 and that is configured to digitize the output signal of the second frontend portion 22.

While not explicitly shown in FIG. 1, the measurement circuit 64 may further be configured to filter, interpolate, and/or decimate the respective signals after digitization.

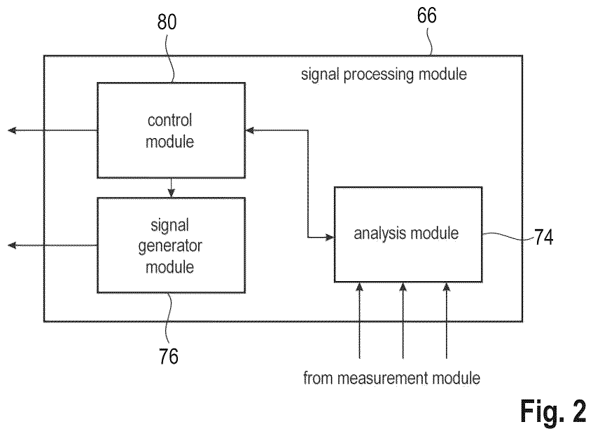

As is illustrated in FIG. 2, the processing circuit 66 comprises an analysis circuit 74 that is connected to the measurement circuit 64, more precisely to the ADCs 68, 70, 72. In general, the analysis circuit 74 is configured to analyze signals received from the measurement circuit 64, as will be described in more detail below.

In an embodiment, the processing circuit 66 further comprises a signal generator circuit 76 that is configured to generate a stimulus RF signal, for example a digital stimulus RF signal.

As is shown in FIG. 1, the VNA base system 14 may comprise a digital-to-analog converter (DAC) 78 that is connected to the signal generator circuit 76 and that is configured to convert the digital stimulus RF signal into an analog stimulus RF signal.

It is to be understood that while the signal generator circuit 76 is shown to be integrated into the processing circuit 66 and thus into the VNA base system 14 in FIGS. 1 and 2, the signal generator circuit 76 may also be established separately from the VNA base system 14, for example in a different housing.

Referring back to FIG. 2, the processing circuit 66 further comprises a control circuit 80. In an embodiment, the control circuit 80 is connected to the switching stage 40, wherein the control circuit 80 is configured to control the switching stage 40 to selectively switch between the first switching state and the second switching state.

In an embodiment, the control circuit 80 may further be configured to set operational parameters of the signal generator circuit 76 and/or of the analysis circuit 74 for performing certain types of measurements.

In an embodiment, the VNA measurement system 10, or more precisely the VNA base system 14 in cooperation with the RF frontend 12, is configured to perform measurements on the device under test as is described hereinafter.

In a first measurement mode, the control circuit 80 controls the switching stage 40 to enter the first switching state. In this first measurement mode, the stimulus RF signal is generated by the signal generator circuit 76, and the stimulus RF signal is forwarded to the frequency combining unit 42 via the first signal path 50 of the switching stage 40.

The stimulus RF signal is coupled into the measurement path 18 by the frequency combining unit 42 and is applied to the device under test via the port 16. Moreover, the stimulus RF signal is coupled out of the measurement path 18 by the first directional unit 28, thereby obtaining the reference signal for performing the measurements.

In an embodiment, a measurement signal is received from the device under test by the port 16, and the measurement signal is coupled out of the measurement path 18 by the second directional unit 34. The measurement signal may correspond to the stimulus RF signal being reflected at the device under test or to the stimulus RF signal that has been processed by the device under test.

The reference signal and the measurement signal are forwarded to the measurement circuit by the reference signal path 26 and the measurement signal path 24, respectively. The reference signal and the measurement signal are digitized by the measurement circuit 64, and the resulting digitized reference signal and the digitized measurement signal are forwarded to the analysis circuit 74.

In an embodiment, the analysis circuit 74 determines at least one measurement parameter based on the digitized reference signal and based on the digitized measurement signal. For example, the at least one measurement parameter comprises at least one scattering parameter, for example at least one S-parameter. However, it is to be understood that any other type of measurement may be performed.

In a second measurement mode, the control circuit 80 controls the switching stage 40 to enter the second switching state. In the second measurement mode, a measurement signal is received from the device under test via the port 16.

The measurement signal is coupled out of the measurement path 18 by the frequency combining unit 42, and the measurement signal is processed by the second signal path 52 of the switching stage 40.

In the example embodiment shown in FIG. 1, the measurement signal is amplified by the first amplifier 54, which may be established as a low-noise amplifier. The measurement signal may then be further amplified by the output amplifier 60, processed by the mixing unit 62, and the resulting measurement signal is forwarded to and digitized by the measurement circuit 64. The digitized measurement signal is forwarded to the analysis circuit 74.

In general, the analysis circuit 74 performs a different type of measurement on the measurement signal in the second measurement mode compared to the first measurement mode. For example, in the second measurement mode, the analysis circuit 74 may be configured to determine at least one noise parameter based on the measurement signal processed by the second signal path 52 of the switching stage 40. In a particular example, the at least one noise parameter may comprise a noise figure.

In an embodiment, the RF frontend 12 described above may only be configured to or be optimized for processing RF signals in a certain frequency range. For example, the RF frontend 12 may be a high-frequency frontend being configured to process frequencies above a predefined threshold, such as 70 GHz. It is to be understood that the threshold may be at any other suitable frequency.

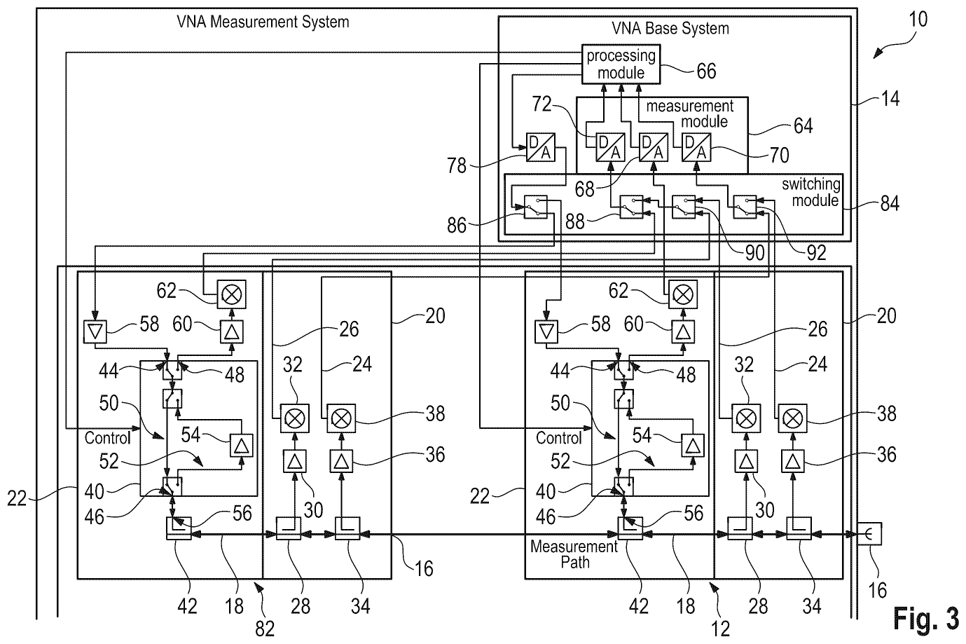

Referring back to FIG. 1, the VNA measurement system 10 may comprise at least one further RF frontend 82. The further RF frontend 82 is described in more detail hereinafter with reference to FIG. 3, which shows a further example embodiment of the VNA measurement system 10.

In general, the at least one further RF frontend 82 may be established analogously to the RF frontend 12, but may be configured for processing signals in a different frequency range, such as in a frequency range below the predefined threshold described above.

Accordingly, while the same reference numerals are used for the individual components of the further RF frontend 82 and of the RF frontend 12 in FIG. 3, it is to be understood that the individual components of the further RF frontend 82 and of the RF frontend 12 may be configured for different frequency ranges.

In an embodiment, the components of the RF frontend 12 may be configured for frequencies above the predefined threshold, while the components of the further RF frontend 82 may be configured for frequencies below the predefined threshold.

Accordingly, the same measurements of the at least one measurement parameter and of the at least one noise parameter described above can be performed by the further RF frontend 82, but with the frequency of the reference signal and of the measurement signal being below the predefined threshold.

In an embodiment, the measurement path 18 may extend through both the RF frontend 12 and the further RF frontend 82. In other words, the measurement paths 18 of the RF frontend 12 and of the further RF frontend 82 may be established as a single continuous signal line.

In an embodiment, the RF frontend 12 and the further RF frontend 82 may be arranged within a common housing. In other words, the common housing may enclose both the RF frontend 12 and the further RF frontend 82. Alternatively, the RF frontend 12 and the further RF frontend 82 may be arranged in separate housings.

In an embodiment, the RF frontend 12 and/or the further RF frontend 82 may be provided separately from the VNA base system 14, e.g. provided in a different housing. Alternatively, the RF frontend 12 and/or the further RF frontend 82 may be integrated into the VNA base system 14.

In the example embodiment shown in FIG. 3, the VNA measurement system 10 further comprises a measurement switching circuit 84 that is interconnected between the RF frontends 12, 82 and the measurement circuit 64. In general, the measurement switching circuit 84 is configured to selectively connect the RF frontend 12 or the further RF frontend 82 to the measurement circuit 64.

Further, the measurement switching circuit 84 may be configured to selectively connect the RF frontend 12 or the further RF frontend 82 to the processing circuit 66.

In an embodiment, the control circuit 80 may be configured to control the measurement switching circuit 84 to selectively connect the RF frontend 12 or the further RF frontend 82 to the measurement circuit 64 and to the processing circuit 66.

Therein, the RF frontend 12 may be selected if the frequency of the reference signal and/or the frequency of the measurement signal is above the predefined threshold, e.g. above 70 GHz. The further RF frontend 82 may be selected if the frequency of the reference signal and/or the frequency of the measurement signal is below the predefined threshold.

In an embodiment, the measurement switching circuit 84 may comprise a first switching unit 86 that is configured to selectively connect the input port 44 of the RF frontend 12 or the input port 44 of the further RF frontend 82 to the signal generator circuit 76.

In an embodiment, the measurement switching circuit 84 may further comprise a second switching unit 88 that is configured to selectively connect the output port 48 of the RF frontend 12 or the output port 48 of the further RF frontend 82 to the measurement circuit 64, for example to the third ADC 72.

In an embodiment, the measurement switching circuit 84 may further comprise a third switching unit 90 that is configured to selectively connect the reference signal path 26 of the RF frontend 12 or the reference signal path 26 of the further RF frontend 82 to the measurement circuit 64, for example to the first ADC 68.

In an embodiment, the measurement switching circuit 84 may further comprise a fourth switching unit 92 that is configured to selectively connect the measurement signal path 24 of the RF frontend 12 or the measurement signal path 24 of the further RF frontend 82 to the measurement circuit 64, for example to the second ADC 70.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the VNA measurement system 10, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure May employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A radio frequency (RF) frontend for a vector network analyzer (VNA) measurement system, the RF frontend comprising:
at least one port being connectable to a device under test;
at least one measurement path that is connected to the at least one port; and
a first frontend portion and a second frontend portion,
wherein the first frontend portion comprises a first directional unit being connected to the at least one measurement path and being configured to couple an RF signal traveling towards the at least one port out of the at least one measurement path, wherein the first frontend portion further comprises a second directional unit being connected to the at least one measurement path and being configured to couple an RF signal traveling away from the at least one port out of the at least one measurement path,
wherein the second frontend portion comprises a frequency combining unit and a switching stage,
wherein the switching stage comprises an input port, a common port, an output port, a first signal path, and a second signal path,
wherein the switching stage has a first switching state, wherein the switching stage is configured to forward a stimulus RF signal received by the input port to the common port via the first signal path in the first switching state,
wherein the switching stage has a second switching state, wherein the switching stage is configured to forward an RF signal received by the common port to the output port via the second signal path in the second switching state,
wherein the frequency combining unit is connected to the at least one measurement path, wherein the frequency combining unit comprises a common port that is connected to the common port of the switching stage, wherein the frequency combining unit is configured to couple the stimulus RF signal into the at least one measurement path, and wherein the frequency combining unit is configured to couple an RF signal traveling away from the at least one port out of the at least one measurement path, such that the RF signal is forwarded to the common port of the frequency combining unit, and
wherein the second frontend portion comprises a first amplifier that is arranged within the second signal path, wherein the first amplifier is configured to amplify the RF signal received from the measurement path via the frequency combining unit, wherein the second frontend portion is configured to obtain an output signal based on the RF signal received from the measurement path via the frequency combining unit.

2. The RF frontend of claim 1, wherein the input port of the switching stage is connected or connectable to a signal source that is configured to generate the stimulus RF signal.

3. The RF frontend of claim 2, wherein the signal source is comprised in a VNA base system.

4. The RF frontend according to claim 1, wherein the output port of the switching stage is connected or connectable to a measurement circuit.

5. The RF frontend of claim 4, wherein the measurement circuit is comprised in a VNA base system.

6. The RF frontend according to claim 1, wherein the second frontend portion comprises a stimulus power amplifier being connected to the input port of the switching stage upstream of the input port, and/or wherein the second frontend portion comprises an output amplifier being connected to the output port of the switching stage downstream of the output port.

7. The RF frontend according to claim 1, wherein the second frontend portion comprises a mixing unit that is connected to the output port of the switching stage downstream of the output port.

8. The RF frontend according to claim 1, wherein the first frontend portion comprises a first pre-amplifier being connected to the first directional unit downstream of the first directional unit, and/or a second pre-amplifier being connected to the second directional unit downstream of the second directional unit.

9. The RF frontend according to claim 1, wherein the first frontend portion comprises a first mixing unit being connected to the first directional unit downstream of the first directional unit, and/or a second mixing unit being connected to the second directional unit downstream of the second directional unit.

10. The RF frontend according to claim 1, wherein the first frontend portion and the second frontend portion are arranged within a common housing.

11. A VNA measurement system, comprising:
an RF frontend according to claim 1; and
a VNA base system comprising a measurement circuit and a processing circuit,
wherein the processing circuit is configured to control the switching stage of the RF frontend to selectively switch between the first switching state of the RF frontend and the second switching state of the RF frontend.

12. The VNA measurement system of claim 11, wherein the VNA base system is configured to receive a reference signal from the first directional unit of the RF frontend, wherein the VNA base system is further configured to receive a measurement signal from the second directional unit of the RF frontend, and wherein the processing circuit is configured to determine at least one measurement parameter based on the reference signal and based on the measurement signal.

13. The VNA measurement system of claim 12, wherein the at least one measurement parameter comprises at least one S-parameter.

14. The VNA measurement system of claim 11, wherein the VNA base system is configured to receive the output signal of the second frontend portion of the RF frontend, wherein the processing circuit is configured to determine at least one noise parameter based on the output signal.

15. The VNA measurement system according to claim 11, wherein the VNA measurement system comprises at least one further RF frontend, wherein the at least one further RF frontend comprises a measurement path, wherein the measurement path of the RF frontend and the measurement path of the at least one further RF frontend are connected with each other.

16. The VNA measurement system of claim 15, wherein the at least one further RF frontend comprises a first frontend portion and a second frontend portion,
wherein the VNA measurement system further comprises a measurement switching circuit, wherein the measurement switching circuit is configured to selectively connect the first frontend portion of the RF frontend or the first frontend portion of the at least one further RF frontend to the VNA base system, and/or wherein the measurement switching circuit is configured to selectively connect the second frontend portion of the RF frontend or the second frontend portion of the at least one further RF frontend to the VNA base system.

17. The VNA measurement system of claim 15, wherein the RF frontend and the at least one further RF frontend are arranged within a common housing.

18. The VNA measurement system according to claim 11, wherein the VNA measurement system comprises a plurality of ports and a plurality of RF frontends, and wherein each port of the plurality of ports is associated with one RF frontend of the plurality of RF frontends.
